(19) United States
(12) Patent Application Publication
(10) Pub. No.: US 2026/0082574 A1
(43) Pub. Date: Mar. 19, 2026

(54) SEMICONDUCTOR DEVICE

(71) Applicant: Kioxia Corporation, Tokyo (JP)

(72) Inventors: Haruna Sugiura, Yokohama Kanagawa (JP); Fumiharu Nakajima, Yokohama Kanagawa (JP); Yoshiyuki Takasu, Yokohama Kanagawa (JP)

(73) Assignee: Kioxia Corporation, Tokyo (JP)

(21) Appl. No.: 19/076,094

(22) Filed: Mar. 11, 2025

(30) Foreign Application Priority Data
Sep. 18, 2024 (JP) 2024-161136

(51) Int. Cl. H10B 43/40; H01L 23/00; H01L 25/065; H01L 25/18; H10B 43/10; H10B 43/27; H10B 80/00

(52) U.S. Cl. CPC H10B 43/40; H10B 43/10; H10B 43/27; H10B 80/00; H10W 90/00; H10W 90/792

(57) ABSTRACT

According to one embodiment, a semiconductor device includes: a control circuit provided on a substrate; and a plurality of conductors provided in a first layer positioned away from the substrate in a first direction. The plurality of conductors include first, second, third, and fourth conductors arranged in this order in a second direction. The control circuit is configured to: apply, in a case of applying a first voltage to the first conductor, a second voltage different from the first voltage to the third and fourth conductors; and be insulated from the second conductor. The third and fourth conductors are aligned in the second direction with a first pitch. The first, second, and third conductors are aligned in the second direction with a second pitch equal to or less than the first pitch.

### CROSS-REFERENCE TO RELATED APPLICATIONS

This application is based upon and claims the benefit of priority from Japanese Patent Application No. 2024-161136, filed Sep. 18, 2024, the entire contents of which are incorporated herein by reference.

### FIELD

Embodiments described herein relate generally to a semiconductor device.

### BACKGROUND

There has been known a NAND flash memory as a semiconductor device capable of storing data in a non-volatile manner. In a semiconductor device such as the NAND flash memory, multiple wirings are arranged in the same layer for achieving high integration and large capacity.

### BRIEF DESCRIPTION OF THE DRAWINGS

FIG. 1 is a block diagram illustrating an example of a configuration of a memory system including a memory device according to a first embodiment.

FIG. 2 is a circuit diagram illustrating an example of a circuit configuration of a memory cell array provided in the memory device according to the first embodiment.

FIG. 3 is a circuit diagram illustrating an example of connections among the memory cell array, a row decoder module, and a driver module that are provided in the memory device according to the first embodiment.

FIG. 4 is a plan view illustrating an example of a planar layout of the memory cell array provided in the memory device according to the first embodiment.

FIG. 5 is a plan view illustrating an example of a region V in FIG. 4, which is a part of the planar layout of the memory cell array provided in the memory device according to the first embodiment

FIG. 6 is a sectional view, taken along a line VI-VI in FIG. 5, illustrating an example of a sectional structure of the memory cell array provided in the memory device according to the first embodiment.

FIG. 7 is a sectional view, taken along a line VII-VII in FIG. 6, illustrating an example of a sectional structure of a memory pillar provided in the memory cell array according to the first embodiment.

FIG. 8 is a perspective view illustrating an overview of a bonding structure of the memory device according to the first embodiment.

FIG. 9 is a sectional view illustrating an example of a sectional structure of the memory device according to the first embodiment.

FIG. 10 is a plan view illustrating an example of a planar layout of wirings in the vicinity of the row decoder module in the memory device according to the first embodiment.

FIG. 11 is a plan view illustrating an example of a planar layout of wirings in the vicinity of a row decoder module in a memory device according to a modification of the first embodiment.

FIG. 12 is a plan view illustrating an example of a planar layout of wirings in the vicinity of a row decoder module in a memory device according to a second embodiment.

FIG. 13 is a plan view illustrating an example of a planar layout of wirings in the vicinity of a row decoder module in a memory device according to a first modification of the second embodiment.

FIG. 14 is a plan view illustrating an example of a planar layout of wirings in the vicinity of a row decoder module in a memory device according to a second modification of the second embodiment.

FIG. 15 is a plan view illustrating an example of a planar layout of wirings in the vicinity of a row decoder module in a memory device according to a third modification of the second embodiment.

FIG. 16 is a plan view illustrating an example of a planar layout of wirings in the vicinity of a row decoder module in a memory device according to a third embodiment.

FIG. 17 is a plan view illustrating an example of a planar layout of wirings in the vicinity of a row decoder module in a memory device according to a fourth embodiment.

### DETAILED DESCRIPTION

In general, according to one embodiment, a semiconductor device includes a control circuit provided on a substrate; and a plurality of conductors provided in a first layer positioned away from the substrate in a first direction. The plurality of conductors include a first conductor, a second conductor, a third conductor, and a fourth conductor arranged in this order in a second direction intersecting the first direction. The control circuit is configured to: apply, in a case of applying a first voltage to the first conductor, a second voltage different from the first voltage to the third conductor and the fourth conductor; and be insulated from the second conductor. The third conductor and the fourth conductor are aligned in the second direction with a first pitch. The first conductor, the second conductor, and the third conductor are aligned in the second direction with a second pitch, the second pitch being equal to or less than the first pitch.

Hereinafter, explanations will be given as to embodiments with reference to the drawings. It should be noted that dimensions and proportions in the drawings are not necessarily identical to actual dimensions and proportions.

In the following descriptions, the same reference numerals are given to components having substantially the same functions and structures. In a case where elements having similar configurations are to be specifically distinguished, mutually different letters or numbers may be added to the end of the same reference numerals.

### 1. First Embodiment

### 1.1 Functional Configuration

### 1.1.1 Memory System

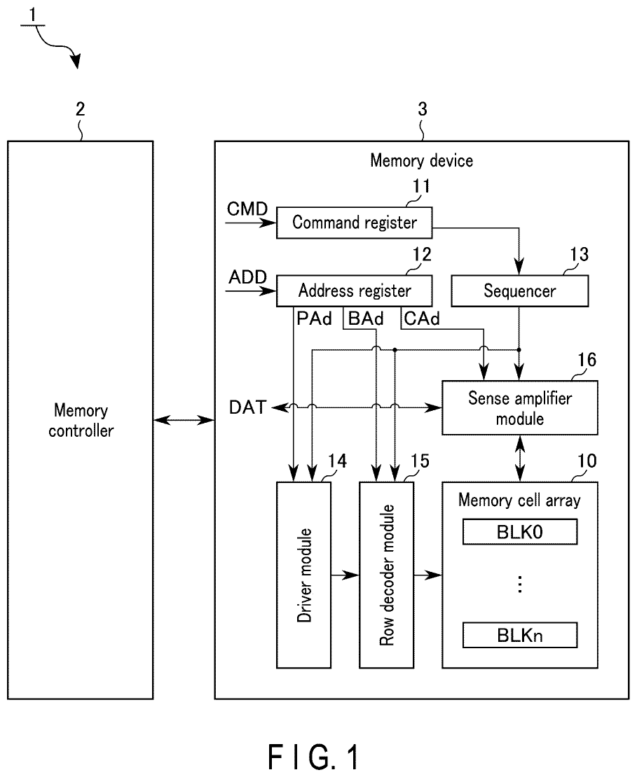

FIG. 1 is a block diagram illustrating an example of a configuration of a memory system including a memory device according to a first embodiment. A memory system 1 is a storage device configured to be connected to an external host (not shown). The memory system 1 is, for example, a memory card such as an SD card, a UFS (universal flash storage) or an SSD (solid state drive). The memory system 1 includes a memory controller 2 and a memory device 3.

The memory controller 2 is configured of an integrated circuit such as an SoC (system-on-a-chip), for example. The memory controller 2 controls the memory device 3 on the basis of a request from a host. Specifically, for example, the memory controller 2 writes into the memory device 3, data that the host requested to write. Further, the memory controller 2 reads from the memory device 3, data that the host requested to read and transmit the read data to the host.

The memory device 3 is a semiconductor device that has a function to store data in a non-volatile manner. The memory device 3 is, for example, a NAND flash memory.

Communications between the memory controller 2 and the memory device 3 conform to, for example, an SDR (single data rate) interface, a Toggle DDR (double data rate) interface, or an ONFI (open NAND flash interface).

1.1.2 Memory Device Next, an explanation will be given, with reference to the block diagram illustrated in FIG. 1, as to the configuration of the memory device according to the first embodiment.

### <Overall Configuration>

The memory device 3 includes, for example, a memory cell array 10, a command register 11, an address register 12, a sequencer 13, a driver module 14, a row decoder module 15, and a sense amplifier module 16.

The memory cell array 10 includes multiple blocks BLK0 to BLKn (n is an integer equal to or greater than 1). The number of the blocks BLK included in the memory cell array 10 may be one. The block BLK is a set of multiple memory cells. The block BLK is used, for example, as a data erasure unit. Further, the memory cell array 10 is provided with multiple bit lines and multiple word lines. Each memory cell is associated with, for example, one bit line and one word line. The detailed configuration of the memory cell array 10 will be described later.

The command register 11 stores a command CMD that the memory device 3 has received from the memory controller 2. The command CMD includes, for example, instructions for causing the sequencer 13 to execute the read operation, the write operation, the erase operation, and so on.

The address register 12 stores address information ADD that the memory device 3 has received from the memory controller 2. The address information ADD includes, for example, a block address BAd, a page address PAd, and a column address CAd. For example, the block address BAd, the page address PAd, and the column address CAd are used respectively for selection of the block BLK, the word line, and the bit line.

The sequencer 13 controls an overall operation of the memory device 3. For example, the sequencer 13 controls, on the basis of the command CMD stored in the command register 11, the driver module 14, the row decoder module 15, the sense amplifier module 16, and so on to execute the read operation, the write operation, the erase operation, and so on.

The driver module 14 generates voltages used for the read operation, the write operation, the erase operation, and so on. The driver module 14 applies, for example, on the basis of the page address PAd stored in the address register 12, the generated voltage to a signal line associated with a selected word line.

The row decoder module 15 selects, on the basis of the block address BAd stored in the address register 12, one block BLK in an associated memory cell array 10. Then, the row decoder module 15 transfers the voltage applied to the signal line associated with the selected word line to the selected word line in the selected block BLK.

The sense amplifier module 16 applies, in the write operation, a desired voltage to each bit line in accordance with write data DAT received from the memory controller 2. Further, the sense amplifier module 16 determines, in the read operation, the data stored in the memory cell on the basis of the voltage of the bit line, and transfers a determination result, as read data DAT, to the memory controller 2.

### <Memory Cell Array>

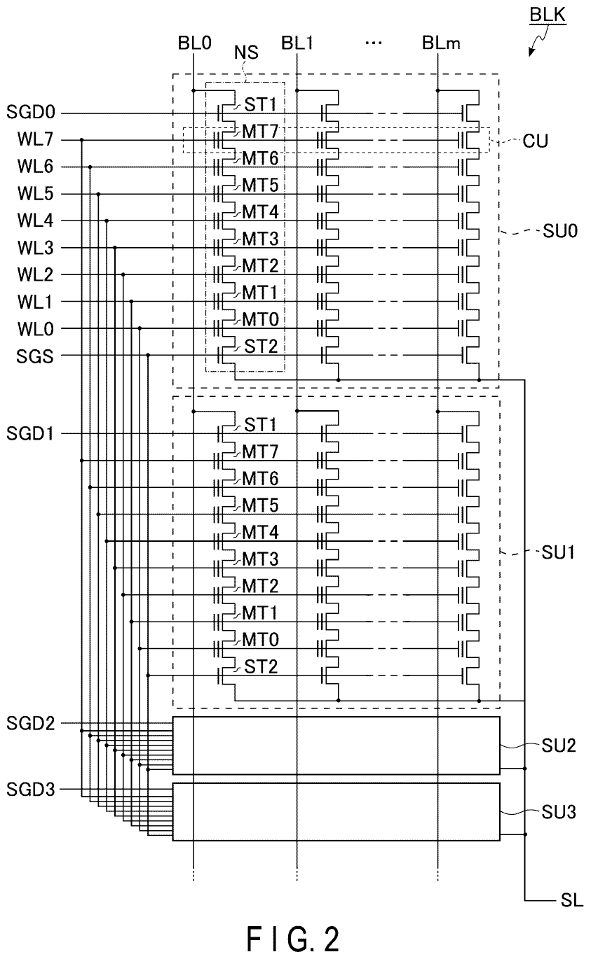

FIG. 2 is a circuit diagram illustrating an example of a circuit configuration of the memory cell array provided in the memory device according to the first embodiment. In FIG. 2, one block BLK of the plural blocks BLK included in the memory cell array 10 is illustrated. As illustrated in FIG. 2, the block BLK includes, for example, four string units SU0 to SU3.

Each string unit SU includes multiple NAND strings NS each being associated with each of bit lines BL0 to BLm (m is an integer equal to or greater than 1). The number of the bit lines BL may be one. Each NAND string NS includes, for example, memory cell transistors MT0 to MT7 and selection transistors ST1 and ST2. Each memory cell transistor MT includes a control gate and a charge storage film, and stores data in a non-volatile manner. Each of the selection transistors ST1 and ST2 is used for selecting the string unit SU in various operations.

In each NAND string NS, the memory cell transistors MT0 to MT7 are connected in series. The drain of the selection transistor ST1 is connected to an associated bit line BL. The source of the selection transistor ST1 is connected to one end of each of the series-connected memory cell transistors MT0 to MT7. The drain of the selection transistor ST2 is connected to the other end of each of the series-connected memory cell transistors MT0 to MT7. The source of the selection transistor ST2 is connected to a source line SL.

In the same block BLK, the control gate of each of the memory cell transistors MT0 to MT7 is connected to a corresponding one of word lines WL0 to WL7. The gate of each of the selection transistors ST1 in the string units SU0 to SU3 is connected to a corresponding one of the selection gate lines SGD0 to SGD3. The gate of each of the multiple selection transistors ST2 is connected to a selection gate line SGS.

A different column address is assigned to each of the bit lines BL0 to BLm. Each bit line BL is shared by NAND strings NS to which the same column address has been assigned among the multiple blocks BLK. Each of the word lines WL0 to WL7 is provided for each block BLK. The source line SL is shared, for example, among the multiple blocks BLK.

A set of plural memory cell transistors MT connected to a common word line WL within one string unit SU is called, for example, a cell unit CU. For example, a storage capacity of the cell unit CU, which includes memory cell transistors MT each storing one-bit data, is defined as “one page data”. The cell unit CU may have a storage capacity of two page data or more, according to the number of bits of the data stored in the memory cell transistor MT.

Incidentally, the circuit configuration of the memory cell array 10 provided in the memory device 3 according to the first embodiment is not limited to the configuration described above. For example, the number of the string units SU included in each block BLK may be designed to be an any number. The number of the memory cell transistors MT and the selection transistors ST1 and ST2 that are included in each NAND string NS may be designed to be any numbers, respectively.

### <Row Decoder Module>

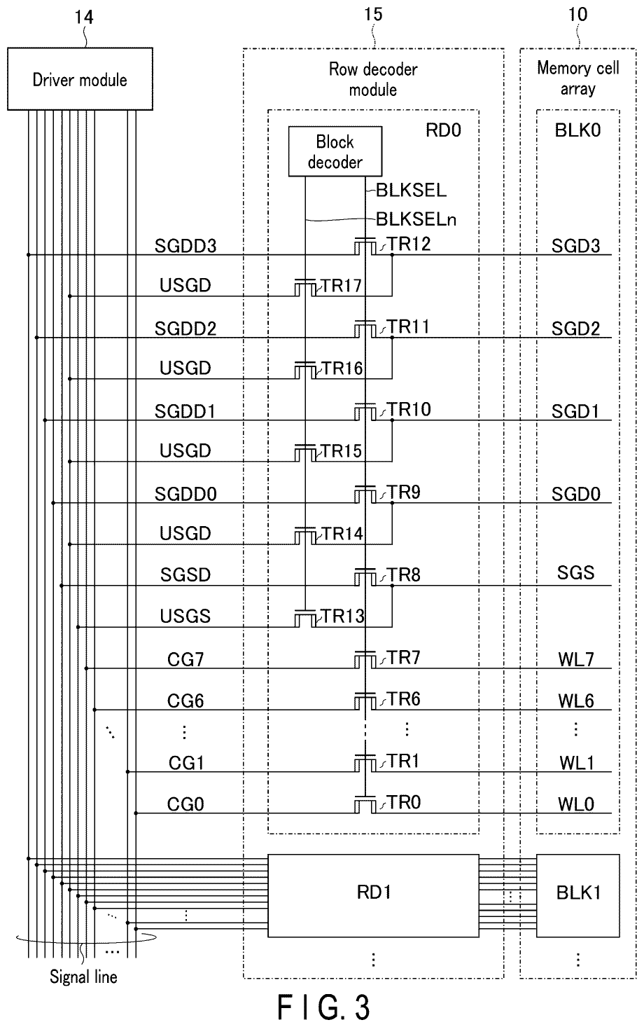

FIG. 3 is a circuit diagram illustrating an example of connections among the memory cell array, the row decoder module, and the driver module according to the first embodiment. As illustrated in FIG. 3, the row decoder module 15 includes multiple row decoders RD (RD0, RD1, . . . ) The number of the row decoders RD corresponds to the number of the blocks BLK. Each of the multiple row decoders RD includes an equivalent configuration. In the example illustrated in FIG. 3, the configuration of the row decoder RD0 associated with the block BLK0 is illustrated. The row decoder RD0 includes a block decoder BD and transistors TR0 to TR17.

Each of the transistors TR0 to TR12 is, for example, an n-type transistor. A first end of each of the transistors TR0 to TR7 is connected to the block BLK0 via a corresponding one of the word lines WL0 to WL7. A second end of each of the transistors TR0 to TR7 is connected to the driver module 14 via a corresponding one of the wiring CG0 to CG7. The gate of each of the transistors TR0 to TR7 is connected to the block decoder BD via a wiring BLKSEL.

For example, in the write operation, each of the transistors TR0 to TR7 can transfer a write voltage to each of the word lines WL0 to WL7. The write voltage is a high voltage of an extent that can raise a threshold voltage of the memory cell transistors MT. Therefore, the transistors TR0 to TR7 have a high breakdown voltage of an extent that can transfer the write voltage. Hereinafter, the transistor having the breakdown voltage of an extent that can transfer the write voltage is referred to as “a high breakdown voltage transistor” or “an HV transistor”. The HV transistor has a gate oxide film thickness of at least 10 nm and, in a case of a transistor that is operable with a voltage up to 30V, the gate oxide film thickness is designed to be approximately 40 nm, for example. Further, a transistor having a lower breakdown voltage relative to the HV transistor is referred to as “a low breakdown voltage transistor” or “an LV transistor”. The LV transistor is designed to have a gate oxide film thickness between 5 nm and 7 nm. A transistor having a further lower breakdown voltage relative to the LV transistor is referred to as “an very low breakdown voltage transistor” or “a VLV transistor”. The VLV transistor is designed to have a gate oxide film thickness between 2.5 nm (inclusive) and 3.5 nm (inclusive).

The transistor TR8 is, for example, an n-type HV transistor. A first end of the transistor TR8 is connected to the block BLK0 via the selection gate line SGS. A second end of the transistor TR8 is connected to the driver module 14 via the wiring SGSD. The gate of the transistor TR8 is connected to the block decoder BD via the wiring BLKSEL.

Each of the transistors TR9 to TR12 is, for example, the n-type HV transistor. A first end of each of the transistors TR9 to TR12 is connected to the block BLK0 via a corresponding one of the selection gate lines SGD0 to SGD3. A second end of each of the transistors TR9 to TR12 is connected to the driver module 14 via a corresponding one of wiring SGDD0 to SGDD3. The gate of each of the transistors TR9 to TR12 is connected to the block decoder BD via the wiring BLKSEL.

The transistor TR13 is, for example, the n-type HV transistor. A first end of the transistor TR13 is connected to the block BLK0 via the selection gate line SGS. A second end of the transistor TR13 is connected to the driver module 14 via a wiring USGS. The gate of the transistor TR13 is connected to the block decoder BD via the wiring BLKSELn.

Each of the transistors TR14 to TR17 is, for example, the n-type HV transistor. A first end of each of the transistors TR14 to TR17 is connected to the block BLK0 via a corresponding one of the selection gate lines SGD0 to SGD3. A second end of each of the transistors TR14 to TR17 is connected to the driver module 14 via the wiring USGD. The gate of each of the transistors TR14 to TR17 is connected to the block decoder BD via the wiring BLKSELn.

The block decoder BD supplies voltages that are mutually different in logic levels to the wirings BLKSEL and BLKSELn. In a case where the block BLK0 is selected, the block decoder BD supplies an “H” level voltage to the wiring BLKSEL, and an “L” level voltage to the wiring BLKSELn. In a case where the block BLK0 is not selected, the block decoder BD supplies the “L” level voltage to the wiring BLKSEL, and the “H” level voltage to the wiring BLKSELn.

### 1.2 Structure

Next, an explanation will be given as to the structure of the memory device according to the first embodiment.

### 1.2.1 Memory Cell Array

First, the detailed structure of the memory cell array 10 will be described.

### <Planar Layout>

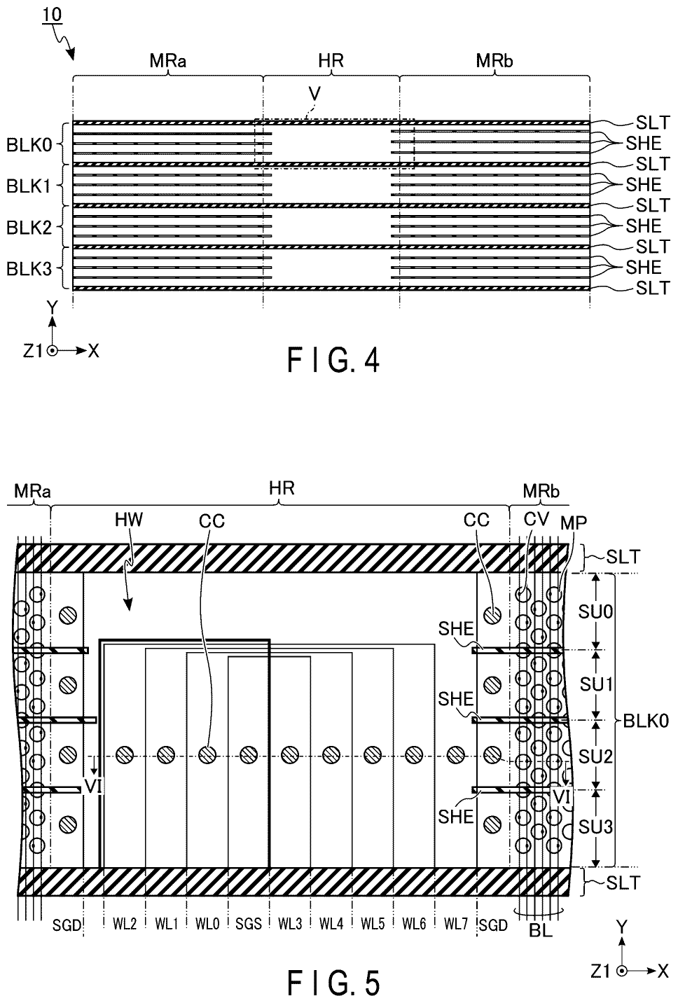

FIG. 4 is a plan view illustrating an example of a planar layout of the memory cell array provided in the memory device according to the first embodiment. In FIG. 4, four blocks BLK0 to BLK3 of the multiple blocks BLK provided in the memory cell array 10 are exemplified.

The memory cell array 10 includes a stacked wiring structure. The stacked wiring structure is a structure in which the wiring layers (word lines WL0 to WL7, and select gate lines SGD and SGS) are stacked.

In the following, a plane approximately parallel to a stacked plane of the wiring layers is referred to as an XY plane. In the XY plane, directions mutually perpendicular to each other are referred to as an X direction and a Y direction. Also, a direction that is approximately perpendicular to the XY plane, and going from the select gate line SGS toward the select gate line SGD, is referred to as a Z1 direction. A direction that is approximately perpendicular to the XY plane, and going from the select gate line SGD toward the select gate line SGS, is referred to as a Z2 direction. In a case where either one of the Z1 direction and the Z2 direction is not limited, the direction is denoted as a Z direction.

As illustrated in FIG. 4, the stacked wiring structure includes memory regions MR and MRb, and a hookup region HR that are aligned in the X direction. The memory regions MRa and MRb are regions where the memory cell transistors MT are provided. The hookup region HR is a region where contacts for electrically connecting each wiring layer with the row decoder module 15 are provided. The hookup region HR is, for example, located between the memory region MRa and the memory region MRb.

Each of the multiple blocks BLK includes a portion, in the stacked wiring structure, extending in the X direction in such a manner as to across the memory region MRa, the hookup region HR, and the memory region MRb. The multiple blocks BLK are aligned in the Y direction. The memory cell array 10 includes, for example, multiple members SLT and multiple members SHE.

Each member SLT extends in the X direction in such a manner as to across the memory region MRa, the hookup region HR, and the memory region MRb. The multiple members SLT are aligned in the Y direction. Each member SLT includes, for example, a structure in which an insulating member is embedded. Each member SLT divides wiring layers adjacent to each other via the members SLT. In the memory cell array 10, each of the regions separated by the members SLT corresponds to one block BLK.

The multiple members SHE include multiple members SHE aligned in the Y direction in the memory region MRa and multiple members SHE aligned in the Y direction in the memory region MRb. Each member SHE located in the memory region MRa extends in the X direction in such a manner as to across the memory region MRa. Each member SHE in the memory region MRb extends in the X direction in such a manner as to across the memory region MRb. In the example in FIG. 4, in each of the memory regions MRa and MRb, three members SHE are arranged between two members SLT that are adjacent to each other in the Y direction. Each member SHE includes, for example, a structure in which an insulator is embedded. Each member SHE divides the selection gate line SGD among the wiring layers adjacent to each other via the members SHE. In the memory cell array 10, each region, which is separated by a pair of members SLT and SHE adjacent to each other or by a pair of two adjacent members SHE, corresponds to one string unit SU.

The planar layout of the memory cell array 10 may be another layout. For example, the number of the members SHE arranged between two adjacent members SLT may be designed to be an any number. The number of the string units SU provided in each block BLOCK may be changed according to the number of the members SHE arranged between two adjacent members SLT.

FIG. 5 is a plan view illustrating an example of a region V in FIG. 4, which is a part of the planar layout of the memory cell array provided in the memory device according to the first embodiment. FIG. 5 illustrates, of the block BLK0, the hookup region HR and boundaries between the hookup region HR and the memory regions MRa and between the hookup region HR and the memory region MRb.

First, an explanation will be given as to the planar layout of the memory cell array 10 in the memory regions MRa and MRb.

As illustrated in FIG. 5, the memory cell array 10 includes, in each of the memory regions MRa and MRb, multiple memory pillars MP, multiple contacts CV, and multiple bit lines BL.

Each memory pillar MP functions as one NAND string NS. The multiple memory pillars MP are arranged, for example, in a staggered pattern with 19 columns in the region between two adjacent members SLT. For example, one member SHE is arranged to overlap with the memory pillar MP in the fifth column, the memory pillar MP in the tenth column, and the memory pillar MP in the fifteenth column, counting from the top of the paper.

The multiple bit lines BL are aligned in the X direction. Each bit line BL is arranged to overlap with at least one memory pillar MP in each string unit SU. In the example illustrated in FIG. 5, two bit lines BL are arranged to overlap with one memory pillar MP. The memory pillar MP is electrically connected, via the contact CV, to one bit line BL of the multiple bit lines BL arranged overlappingly. On the other hand, the contact CV between the memory pillar MP and the bit line BL, being in contact with two different gate lines SGD (that is, being arranged to overlap with the member SHE), may be omitted.

The planar layout in the memory region MR may be another layout. For example, the number and arrangement of the memory pillars MP and the members SHE arranged between two adjacent members SLT may be appropriately changed. The number of bit lines BL that overlap with each memory pillar MP may be designed to be an any number.

Next, an explanation will be given as to the planar layout of the memory cell array 10 in the hookup region HR.

In the hookup region HR, the memory cell array 10 includes multiple contacts CC. Further, in the hookup region HR, the stacked wiring structure includes a terrace portion and a highway portion HW. The terrace portion is a portion where the wiring layers configuring the stacked wiring structure do not overlap with upper wiring layers in the Z1 direction. The highway portion HW is a portion that aligns with the terrace portion in the Y direction.

The stacked wiring structure configures a stepped structure in the terrace portion. In the example illustrated in FIG. 5, steps are formed between the select gate line SGS and the word line WL0, between the word line WL0 and the word line WL1, . . . between the word line WL6 and the word line WL7, and between the word line WL7 and the select gate line SGD, respectively. It should be noted that not all the steps need to be aligned in one direction. For example, the select gate line SGS and some of the word lines WL0 to WL7 (in the example illustrated in FIG. 5, the select gate line SGS and the word lines WL0 to WL2) may form steps in a descending order in the X direction, while the remaining word lines (in the example illustrated in FIG. 5, the word lines WL3 to WL7) may form steps in an ascending order in the X direction. Further, for example, the select gate line SGS and some of the word lines WL0 to WL7 may form steps in the Y direction.

The wiring layer in the memory region MRa and the wiring layer in the memory region MRb are continuously provided via the highway portion HW, except for the select gate line SGD. That is, the highway portion HW is a portion that electrically connects the wiring layers, excluding the select gate line SGD, between the memory region MRa and the memory region MRb. The select gate lines SGD are separated, by the hookup region HR, into the portion of the memory region MRa and the portion of the memory region MRb.

The contacts CC are conductors used for connection between the row decoder module 15 and each of the wiring layers. The multiple contacts CC associated with the block BLK are each connected to the select gate lines SGS and SGD, and the terrace portions of the word lines WL0 to WL7 that are formed in the hookup region HR. To the select gate line SGD on the memory region MRa side and the select gate line SGD on the memory region MRb side, separate contacts CC are provided, respectively. The select gate line SGD on the memory region MRa side and the select gate line SGD on the memory region MRb side, which are associated with the same string unit SU, are electrically connected, for example, via respective contacts CC, wiring layers in the upper layers (not shown), and so on.

### <Sectional Structure>

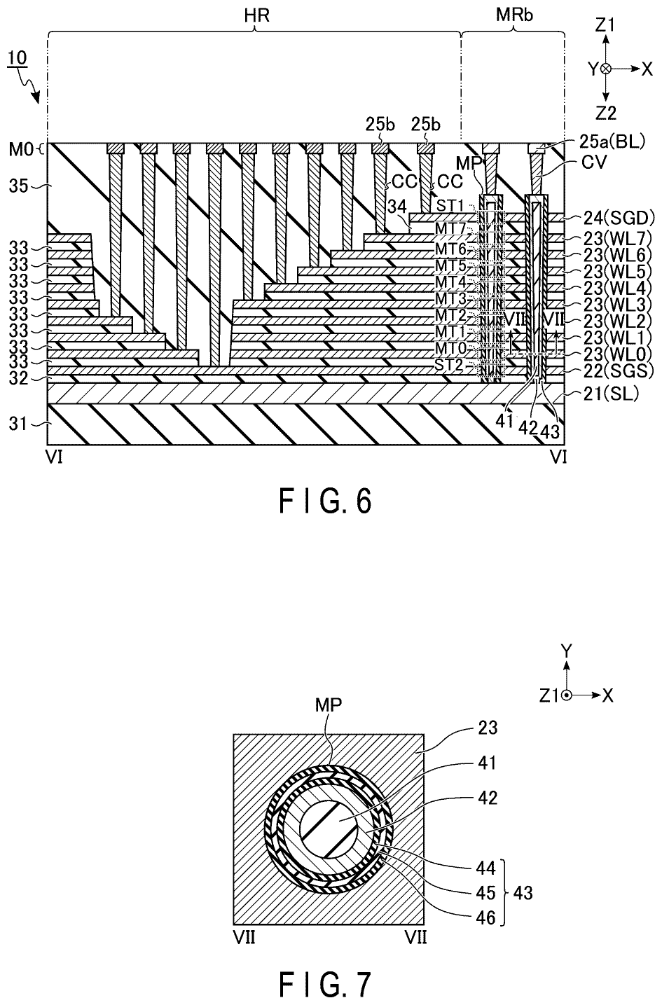

FIG. 6 is a sectional view, taken along a line V1-V1 in FIG. 5, illustrating an example of a sectional structure of the memory sell array provided in the memory device according to the first embodiment. In FIG. 6, the sectional structure of the memory region MRb and a part of the hookup region HR is illustrated.

As illustrated in FIG. 6, the memory cell array 10 includes, for example, the semiconductor layer 21, the wiring layers 22, 23, and 24, the conductive layers 25 (25a and 25b), and the insulating layers 31, 32, 33, 34, and 35. The insulating layers 31 to 35 contain, for example, silicon oxide. In FIG. 6, the Z1 direction corresponds to the upward direction of the paper of the drawing.

On the insulating layer 31, the semiconductor layer 21 is provided. The semiconductor layer 21 is formed, for example, in a flat plate shape extending along the XY plane. The semiconductor layer 21 contains, for example, silicon and is used as the source line SL.

On the semiconductor layer 21, the insulating layer 32 is provided. On the insulating layer 32, the wiring layer 22 is provided. The wiring layer 22 is formed, for example, in a flat plate shape extending along the XY plane. The wiring layer 22 contains, for example, tungsten and is used as the select gate line SGS.

On the wiring layer 22, multiple insulating layers 33 and multiple wiring layers 23 are alternately provided. The multiple wiring layers 23 are formed, for example, in a flat plate shape extending along the XY plane. The multiple wiring layers 23 contain, for example, tungsten and are used respectively as the word lines WL0 to WL7, sequentially in this order from the semiconductor layer 21 side.

On the uppermost layer of the wiring layer 23, the insulating layer 34 is provided. On the insulating layer 34, the wiring layer 24 is provided. The wiring layer 24 is formed, for example, in a plate shape extending along the XY plane. The wiring layer 24 contains, for example, tungsten and is used as the select gate line SGD.

In the memory region MRb, each of multiple memory pillars MP extends in the Z direction and penetrates through the wiring layers 22 to 24 and the insulating layers 32 to 34. Although not illustrated in FIG. 6, multiple memory pillars MP are provided also in the memory region MRa in a similar manner.

Each of the multiple memory pillars MP includes, for example, a core film 41, a semiconductor film 42, and a stacked film 43. The core film 41 is an insulator extending in the Z direction. The semiconductor film 42 covers the core film 41. A lower part of the semiconductor film 42 is in contact with the semiconductor film 21. The stacked film 43 covers the side surface of the semiconductor film 42.

FIG. 7 is a sectional view, taken along the VII-VII line in FIG. 6, illustrating an example of the sectional structure of the memory pillar provided in the memory device according to the first embodiment. In FIG. 7, a cross section that includes the memory pillar MP and the wiring layer 23 and that is parallel to the XY-plane is illustrated. As illustrated in FIG. 7, the stacked film 43 includes, for example, a tunnel insulating film 44, a charge storage film 45, and a block insulating film 46.

The core film 41 is provided, for example, at a central part of the memory pillar MP. The semiconductor film 42 encloses the side surface of the core film 41. The tunnel insulating film 44 encloses the side surface of the semiconductor film 42. The charge storage film 45 encloses the side surface of the tunnel insulating film 44. The block insulating film 46 encloses the side surface of the charge storage film 45. The wiring layer 23 encloses the side surface of the block insulating film 46. The semiconductor film 42 is used as a channel (current path) for the memory cell transistors MT0 to MT7 and the select transistors ST1 and ST2. Each of the tunnel insulating film 44 and the block insulating film 46 contains, for example, silicon oxide. The charge storage film 45 contains, for example, silicon nitride.

With the configuration described above, each of the memory pillars MP functions as one NAND string NS. That is, a portion where the memory pillar MP intersects with the wiring layer 22 functions as the select transistor ST2. A portion where the memory pillar MP intersects with the wiring layer 23 functions as the memory cell transistor MT. A portion where the memory pillar MP intersects with the wiring layer 24 functions as the select transistor ST1.

On the upper surface of the semiconductor film 42 in the memory pillar MP in the Z1 direction, the contact CV is provided. On the upper surface of the contact CV in the Z1 direction, the conductive layer 25a is provided. The conductive layer 25a is formed, for example, in a line shape extending in the Y direction. The conductive layer 25a contains, for example, copper and is used as the bit line BL.

In the hookup region HR, each of the multiple contacts CC extends in the Z direction. Each of the multiple contacts CC contacts with the terrace portions of the associated wiring layers 22 to 24 and are provided away from the non-associated wiring layers 22 to 24.

On the upper surface of the contact CC in the Z1 direction, the conductive layer 25b is provided. The conductive layer 25b contains, for example, copper and is provided in the same layer as the conductive layer 25a. In the following, the layer where the conductive layers 25a and 25b are provided is referred to as a layer M0.

An insulating layer 35 is provided so as to cover the stacked wiring structure, the contacts CC and CV, and the conductor layers 25a and 25b described above.

### 1.2.2 Memory Device

Next, an explanation will be given as to the overall structure of the memory device 3.

### <Bonding Structure>

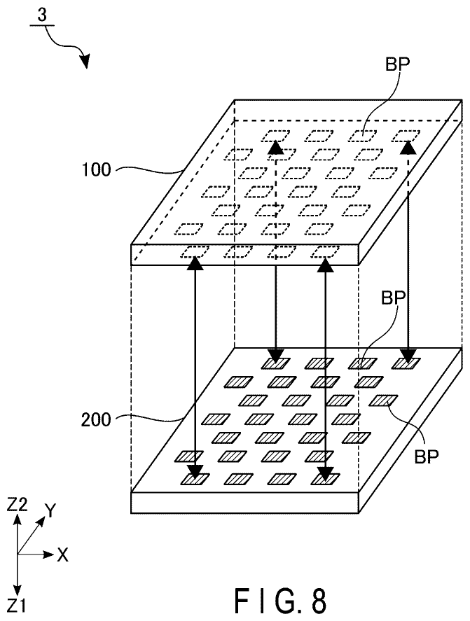

FIG. 8 is a perspective view illustrating an overview of a bonding structure of the memory device according to the first embodiment. As illustrated in FIG. 8, the memory device 3 includes a memory chip 100 and a circuit chip 200. The memory chip 100 includes a structure corresponding to the memory cell array 10. The circuit chip 200 includes, for example, structures corresponding to the command register 11, the address register 12, the sequencer 13, the driver module 14, the row decoder module 15, and the sense amplifier module 16.

Furthermore, each of the memory chip 100 and the circuit chip 200 includes multiple bonding pads BP. The memory device 3 is formed by bonding the memory chip 100 and the circuit chip 200 together via the multiple bonding pads BP. In other words, the side of the circuit chip 200 in the Z2 direction is bonded to the side of the memory chip 100 in the Z1 direction.

### <Sectional Structure>

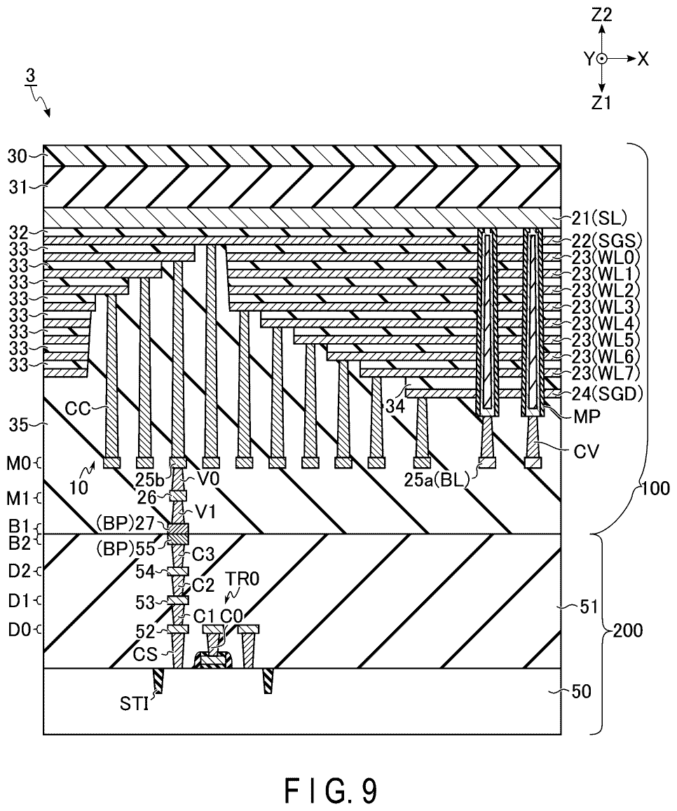

FIG. 9 is a sectional view illustrating an example of a sectional structure of the memory device according to the first embodiment. In FIG. 9, the Z2 direction corresponds to the upward direction of the paper of the drawing.

As illustrated in FIG. 9, the memory device 3 further includes, in the memory chip 100, conductive layers 26 and 27, a protection layer 30, and contacts V0 and V1. The memory device 3 includes, in the circuit chip 200, a substrate 50, an insulating layer 51, conductive layers 52, 53, 54, and 55, an insulating member STI, a transistor TR0, and contacts CS, C0, C1, C2, and C3.

First, an explanation will be given as to the memory chip 100.

The protection layer 30 is provided on the upper surface of the insulating layer 31 in the Z2 direction. The protection layer 30 is a layer corresponding to the surface of the memory device 3 and contains, for example, a resin material such as polyimide. In a region not illustrated in the figure, a part of the protection layer 30 is removed. Then, in a portion where the protection layer 30 has been removed, a power pad responsible for electrical connection with the outside is provided.

On the upper surface of each of the conductive layers 25a and 25b in the Z1 direction, the contact V0 is provided. On the upper surface of the contact V0 in the Z1 direction, the conductive layer 26 is provided.

On the upper surface of the conductive layer 26 in the Z1 direction, the contact V1 is provided. On the upper surface of the contact V1 in the Z1 direction, the conductive layer 27 is provided. The conductive layer 27 functions as the bonding pad BP at the bonding surface between the memory chip 100 and the circuit chip 200. The conductive layers 26 and 27, and the contacts V0 and V1 are covered by the insulating layer 35. In the following, layers where the conductive layers 26 and 27 are provided are referred to as a layer M1 and a bonding layer B1, respectively.

Next, an explanation will be given as to the circuit chip 200.

The substrate 50 is a silicon substrate. On the upper surface of the substrate 50 in the Z2 direction, an insulating layer 51 is provided. On the substrate 50 and the insulating layer 51, multiple transistors TR are provided. The multiple transistors TR configure various circuits to be provided in the circuit chip 200. In FIG. 9, as an example, among the multiple transistors TR, the transistor TR0 which configures the row decoder module 15 is illustrated.

On the upper surface of the gate electrode of the transistor TR0 in the Z2 direction, the contact C0 is provided. On the upper surface of the region, in the Z2 direction, of the substrate 50, which functions as the source or the drain of the transistor TR0, the contact CS is provided. On the upper surface of each of the contacts C0 and CS in the Z2 direction, a conductive layer 52 is provided.

On the upper surface of the conductive layer 52 in the Z2 direction, the contact C1 is provided. On the upper surface of the contact C1 in the Z2 direction, the conductive layer 53 is provided. On the upper surface of the conductive layer 53 in the Z2 direction, the contact C2 is provided. On the upper surface of the contact C2 in the Z2 direction, the conductive layer 54 is provided. On the upper surface of the conductive layer 54 in the Z2 direction, the contact C3 is provided. On the upper surface of the contact C3 in the Z2 direction, the conductive layer 55 is provided. The conductive layer 55 is in contact with the associated conductive layer 27 and functions as the bonding pad BP on the bonding surface between the circuit chip 200 and the memory chip 100. The conductive layers 52, 53, 54, and 55 and the contacts CS, C0, C1, C2, and C3 are covered by the insulating layer 51. In the following, layers where the conductive layers 52, 53, 54, and 55 are provided are referred to as layers D0, D1, and D2, and a bonding layer B2, respectively.

### 1.2.3 Row Decoder Module

Next, an explanation will be given as to the wiring layout in the vicinity of the row decoder module 15.

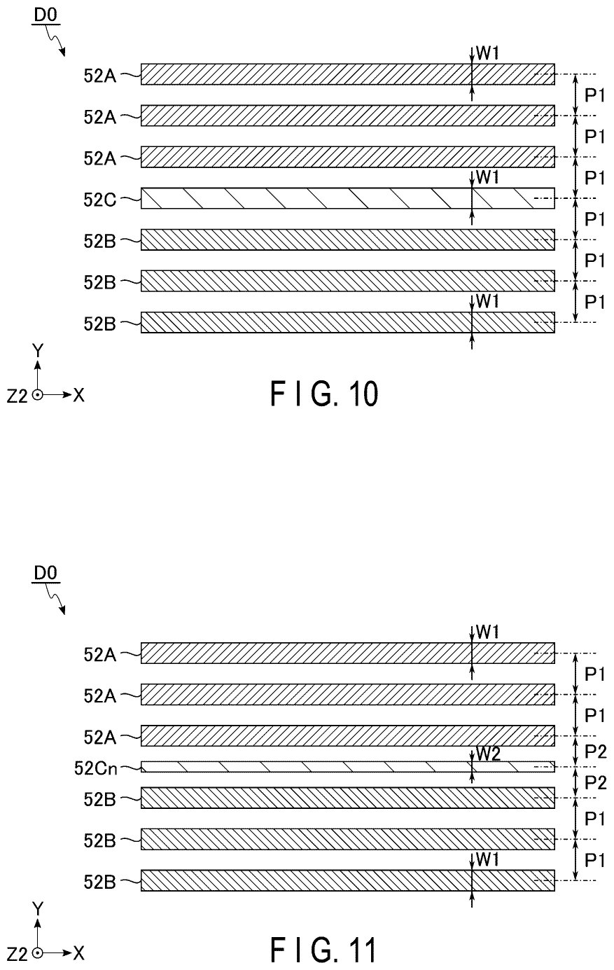

FIG. 10 a plan view illustrating an example of a planar layout of wirings in the vicinity of the row decoder module of the memory device according to the first embodiment. In FIG. 10, an example of the planar layout of the multiple conductive layers 52 provided in the layer D0 is illustrated.

FIG. 10 illustrates, as an example, the planar layout of the layer D0, however, the vicinity of the row decoder module 15 is not limited to the layer D0. For example, the layers D1 and D2 and the like are also in the vicinity of the row decoder module 15 and may have features similar to the planar layout in the layer D0, as described below.

As illustrated in FIG. 10, in the layer D0, the multiple conductive layers 52 form a periodic line and space pattern. The multiple conductive layers 52 include multiple conductive layers 52A, 52B, and 52C.

The multiple conductive layers 52A are a group of wirings in which a relatively large potential difference does not occur mutually at the time of the write operation, the read operation, and so on. Each of the multiple conductive layers 52A extends in the X direction. The multiple conductive layers 52A are aligned at equal intervals in the Y direction with a pitch P1. Each of the multiple conductive layers 52A has a line width W1. That is, a space between two adjacent conductive layers 52A becomes (P1−W1). The pitch P1 and the line width W1 are, for example, 120 nm or less, and 60 nm or less, respectively.

The multiple conductive layers 52B are a group of wirings in which a relatively large potential difference does not occur mutually at the time of the write operation, the read operation, and so on. Each of the multiple conductive layers 52B extends in the X direction. The multiple conductive layers 52B are aligned at equal intervals in the Y direction with the pitch P1. Each of the conductive layers 52B has the line width W1. That is, a space between two adjacent conductive layers 52B becomes (P1−W1).

In a certain operation, a potential difference between a voltage applied to the multiple conductive layers 52B and a voltage applied to the multiple conductive layers 52A may become relatively large. For example, in a case where a high voltage is applied to the multiple conductive layers 52A, a low voltage may be applied to the multiple conductive layers 52B. In a case where a low voltage is applied to the multiple conductive layers 52A, a high voltage may be applied to the multiple conductive layers 52B. In the following, a potential difference between the voltage applied to the multiple conductive layers 52B and the voltage applied to the multiple conductive layers 52A in a certain operation is assumed to be, for example, 15 V or more. Furthermore, a potential difference between the voltages applied to the multiple conductive layers 52A and a potential difference between the voltages applied to the multiple conductive layers 52B in a certain operation are assumed to be, for example, less than 15 V.

The conductive layer 52C is a wiring (in a floating state) to which a predetermined voltage is not applied at the time of the write operation, the read operation, and so on. In other words, the conductive layer 52C is electrically insulated from various circuits formed on the substrate 50, such as the row decoder module 15. The conductive layer 52C extends in the X direction. The conductive layer 52C is provided between multiple conductive layers 52A and multiple conductive layers 52B. The conductive layer 52C and the conductive layer 52A adjacent to the conductive layer 52C are aligned in the Y direction at the pitch P1. The conductive layer 52C and the conductive layer 52B adjacent to the conductive layer 52C are also aligned in the Y direction at the pitch P1. The conductive layer 52C has the line width W1. That is, both of a space between the conductive layer 52C and the adjacent conductive layer 52A and a space between the conductive layer 52C and the adjacent conductive layer 52B, become (P1−W1).

AS such, in the layer D0, the multiple conductive layers 52A, 52B, and 52C are aligned at equal intervals in the Y direction with the pitch P1. In this case, a space between the conductive layers 52A and 52B that are adjacent to each other via the conductive layer 52C (not including the line width of the conductive layer 52C), becomes (P1−W1)×2. This space (P1−W1)×2 between the conductive layer 52A and the conductive layer 52B is designed such that a breakdown voltage of the insulator provided in this space exceeds a potential difference that may occur between the conductive layer 52A and the conductive layer 52B. In other words, the space (P1−W1)×2 between the conductive layer 52A and the conductive layer 52B is designed to be equal to or greater than a threshold value based on the potential difference between the conductive layers 52A and the conductive layer 52B.

As described above, between the multiple conductive layers 52A, a potential difference of that may occur between the conductive layers 52A and the conductive layer 52B, does not occur. Between the multiple conductive layers 52B, a potential difference of that may occur between the conductive layers 52A and the conductive layer 52B, does not occur. Therefore, the space (P1−W1) between two adjacent conductive layers 52A, and the space (P1−W1) between two adjacent conductive layers 52B, may be designed so that the breakdown voltage of the insulators provided in these spaces becomes below the potential difference that may occur between the conductive layer 52A and the conductive layer 52B. In this case, for the conductive layer 52A and the conductive layer 52C, which are adjacent to each other with the space (P1−W1) in between, and the conductive layer 52B and the conductive layer 52C, which are adjacent to each other with the space (P1−W1) in between, it may similarly be designed to be less than the threshold value based on the potential difference between the conductive layers 52A and the conductive layer 52B.

### 1.3 Effects of First Embodiment

According to the first embodiment, the conductive layer 52C is arranged between the conductive layer 52A and the conductive layer 52B. The space (P1−W1)×2 between the conductive layer 52A and the conductive layer 52B becomes equal to or greater than the threshold value based on the potential difference between the conductive layer 52A and the conductive layer 52B. The space (P1−W1) between the conductive layer 52A and the conductive layer 52C, and the space (P1−W1) between the conductive layer 52B and the conductive layer 52C, become less than the threshold value based on the potential difference between the conductive layer 52A and the conductive layer 52B. With this configuration, it is possible to improve a lithographic margin (process margin), while ensuring the breakdown voltage of the insulators provided in the space between the conductive layer 52A and the conductive layer 52B.

To add further, in accordance with increase in the number of stacked layers of the word lines WL, the number of wiring connecting between the row decoder module 15 and the word lines WL increases. Along with increase in the number of wiring, the conductive layers 52, which are arranged in the layer D0, are required to be miniaturized (narrower pitches). On the other hand, under the illumination condition for realizing the fine pattern formation, there is a case where a lithographic margin of an intermediate pitch around twice a minimum pitch may decrease. For this reason, in a case where a narrow pitch such that the minimum pitch becomes 120 nm or less, it is required to form the pattern without using the intermediate pitch.

According to the first embodiment, while arranging the conductive layer 52C between the conductive layer 52A and the conductive layer 52B, the conductive layers 52A, 52B, and 52C are arranged at equal intervals with the pitch P1. With this arrangement, it is possible to make the space (P1−W1)×2 between the conductive layer 52A and the conductive layer 52B to be double the space (P1−W1) between the adjacent conductive layers 52. Therefore, it is possible to ensure the breakdown voltage of the insulators provided between the conductive layer 52A and the conductive layer 52B.

Further, by arranging the conductive layer 52C between the conductive layers 52A and 52B, it is possible to suppress the pitch between the adjacent conductive layers 52A and 52B from becoming the intermediate pitch, which is about twice the pitch P1. For this reason, it is possible to avoid application of a pitch with which the lithographic margin locally decreases under the illumination condition for achieving fine pattern formation.

In addition, by arranging the conductive layers 52A, 52B and 52C at equal intervals with the pitch P1, it is possible to improve the lithographic margin compared to an arrangement where the pitch varies.

### 1.4 Modifications of First Embodiment

Various modifications can be applied in the first embodiment. In the following, explanations will be given mainly as to the configuration different from the first embodiment. As to the configurations that are equivalent to those in the first embodiment, explanations will be omitted as appropriate.

In the first embodiment described above, the explanation has been given as to the case where the multiple conductive layers 52A, 52B, and 52C are aligned in the Y direction at equal intervals with the pitch P1, but it is not limited to this. For example, the pitch between the adjacent conductive layers 52A and 52C, and the pitch between the adjacent conductive layers 52B and 52C, may be shorter than the pitch P1.

FIG. 11 is a plan view illustrating an example of a planar layout of wiring in the vicinity of a row decoder module in the memory device according to a modification of the first embodiment. FIG. 11 corresponds to FIG. 10 in the first embodiment.

As illustrated in FIG. 11, in the layer D0, the multiple conductive layers 52 may include the conductive layers 52A, 52B, and 52Cn.

The conductive layer 52Cn is a wiring to which a specified voltage is not applied (namely, it is in a floating state) at the time of the write operation, the read operation, and so on. The conductive layer 52Cn extends in the X direction. The conductive layer 52Cn is provided between the multiple conductive layers 52A and the multiple conductive layers 52B. The conductive layer 52Cn and the conductive layer 52A adjacent to the conductive layer 52Cn are aligned in the Y direction at a pitch P2 which is shorter than the pitch P1. The conductive layer 52Cn and the conductive layer 52B adjacent to the conductive layer 52Cn are aligned in the Y direction at the pitch P2. The conductive layer 52Cn has a line width W2 shorter than the line width W1. That is, both of the space between the conductive layer 52Cn and the adjacent conductive layers 52A and the space between the conductive layer 52Cn and the adjacent conductive layers 52B, become (P2−W1/2−W2/2). The pitch P2 and the line width W2 are, for example, 110 nanometers (nm) or less and 55 nm or less, respectively. As described above, since the conductive layer 52Cn is the wiring in the floating state, the conductive layer 52Cn is not subject to the restriction regarding the wiring resistance, different from the conductive layer 52A and the conductive layer 52B. For this reason, it is possible to make the pitch P2 and the line width W2 with respect to the conductive layer 52Cn shorter than the pitch P1 and the line width W1 with respect to the conductive layers 52A and 5B that are subject to the restriction regarding the wiring resistance.

The space (not including the line width of the conductive layer 52Cn) between the conductive layer 52A and the conductive layer 52B that are adjacent to each other via the conductive layer 52Cn becomes (P2−W1/2−W2/2)×2. This space (P2−W1/2−W2/2)×2 between the conductive layer 52A and the conductive layer 52B is designed so that the breakdown voltage of the insulators provided in this space exceeds the potential difference that may occur between the conductive layer 52A and the conductive layer 52B.

As described above, by shortening the pitch between the conductive layer 52A and the conductive layer 52Cn, and between the conductive layer 52B and the conductive layer 52Cn, to the pitch P2 that is shorter than the pitch P1, it is possible to reduce the layout size of the conductive layer 52 in the layer D0 within a range that satisfies the constraints of the breakdown voltage.

### 2. Second Embodiment

Next, an explanation will be given as to a memory device according to a second embodiment. In the second embodiment, the planar layout in the vicinity of the wiring that functions as a pad is illustrated. In the following, explanations will be given mainly as to the configuration different from that in the first embodiment. As to the configurations that are equivalent to those in the first embodiment, explanations will be omitted as appropriate.

### 2.1 Configuration

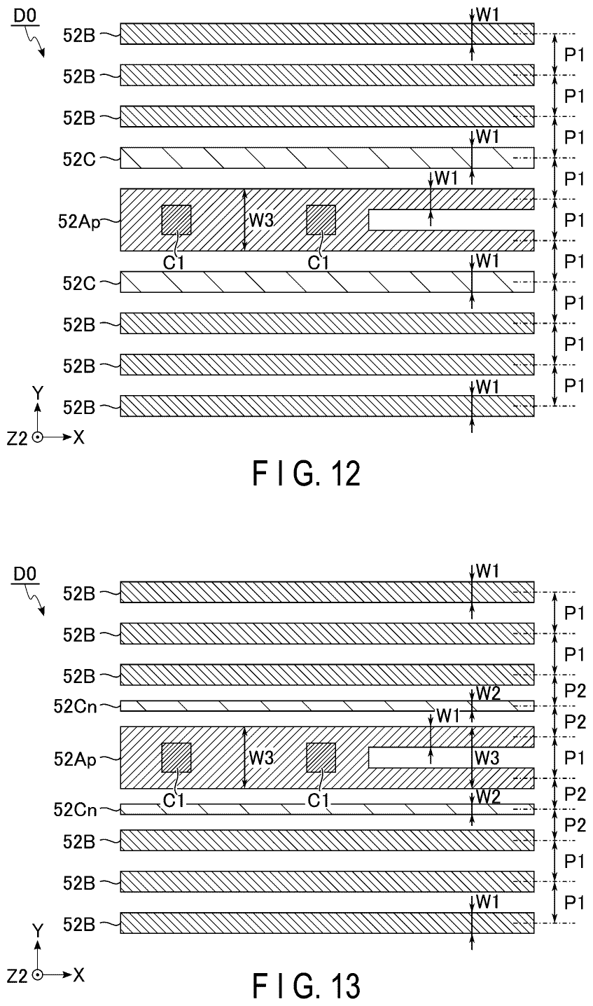

FIG. 12 is a plan view illustrating an example of a planar layout of wiring in the vicinity of a row decoder module of the memory device according to the second embodiment. FIG. 12 corresponds to FIG. 10 in the first embodiment.

As illustrated in FIG. 12, in the layer D0, the multiple conductive layers 52 include the multiple conductive layers 52Ap, 52B, and 52C.

The conductive layer 52Ap is, for example, a wiring that includes a pad portion connected to the contacts C1. The pad portion of the conductive layer 52Ap has a line width W3. The line width W3 is designed so as to be an odd multiple of the line width W1. In the example in FIG. 12, a case where the line width W3 is three times the line width W1 is illustrated.

In addition, the conductive layer 52Ap may further include a wiring portion connected to the pad portion and extending in the X direction. The wiring portion of the conductive layer 52Ap has the line width W1. By making the pad portion of the conductive layer 52Ap an odd multiple of the line width W1, the wiring portion of the conductive layer 52Ap can be provided in the Y direction with the pitch P1.

The multiple conductive layers 52B are a group of wirings in which a relatively large potential difference does not occur mutually at the time of the write operation, the read operation, and so on. The multiple conductive layers 52B are aligned in the Y direction in a manner as to sandwich the conductive layer 52Ap. The mutually adjacent multiple conductive layers 52B are aligned in the Y direction at equal intervals with the pitch P1. Each of the multiple conductive layers 52B has the line width W1. That is, the space between two adjacent conductive layers 52B becomes (P1−W1).

In a certain operation, a potential difference between the voltage applied to the multiple conductive layers 52B and the voltage applied to the conductive layer 52Ap may become relatively large. For example, in a case where a high voltage is applied to the conductive layer 52Ap, a low voltage may be applied to the multiple conductive layers 52B. In a case where a low voltage is applied to the conductive layer 52Ap, a high voltage may be applied to the multiple conductive layers 52B.

The conductive layers 52C are provided between the conductive layer 52Ap and the multiple conductive layers 52B which are aligned with the pitch P1. The conductive layer 52C is a wiring to which a predetermined voltage is not applied in the write operation, the read operation, and so on (that is, in a floating state). The conductive layer 52C and the conductive layer 52B adjacent to the conductive layer 52C are aligned in the Y direction with the pitch P1. The conductive layer 52C and the wiring portion of the conductive layer 52Ap are aligned in the Y direction with the pitch P1. The conductive layer 52C has the line width W1. That is, both of the space between the conductive layer 52Ap and the conductive layer 52C, which are adjacent to each other, and the space between the conductive layer 52B and the conductive layer 52C, which are adjacent to each other, become (P1−W1).

As such, in the layer D0, the wiring portion of the multiple conductive layers 52Ap, the conductive layers 52B and 52C are aligned in the Y direction at equal intervals with the pitch P1. In this case, the space (not including the line width of the conducive layer 52C) between the conductive layer 52Ap and the conductive layer 52B that are adjacent to each other via the conductive layer 52C becomes (P1−W1)×2. This space (P1−W1)×2 between the conductive layer 52Ap and the conductive layer 52B is designed such that a breakdown voltage of the insulator provided in this space exceeds a potential difference that may occur between the conductive layer 52Ap and the conductive layer 52B.

As described above, between the multiple conductive layer 52B, a potential difference of a magnitude that may occur between the conductive layer 52Ap and the conductive layer 52B, does not occur. Therefore, the space (P1−W1) between two adjacent conductive layers 52B may be designed such that the breakdown voltage of the insulator provided in this space becomes lower than the potential difference that may occur between the conductive layer 52Ap and the conductive layer 52B.

### 2.2 Effects of Second Embodiment

According to the second embodiment, the conductive layer 52C is arranged between the conductive layer 52Ap and the conductive layer 52B. The space (P1−W1)×2 between the wiring portion of the conductive layer 52Ap and the conductive layer 52B becomes equal to or greater than the threshold value based on the potential difference between the conductive layer 52Ap and the conductive layer 52B. The space (P1−W1) between the wiring portion of the conductive layer 52Ap and the conductive layer 52C, and the space (P1−W1) between the conductive layer 52B and the conductive layer 52C become less than the threshold value based on the potential difference between the conductive layer 52Ap and the conductive layer 52B. With this arrangement, similarly to the first embodiment, it is possible to improve the lithographic margin while ensuring the breakdown voltage of the insulator provided in the space between the conductive layer 52Ap and the conductive layer 52B.

### 2.3 Modifications of Second Embodiment

The second embodiment can apply various modifications.

### 2.3.1 First Modification of Second Embodiment

In the second embodiment, the explanation has been given as to the case where the wiring portion of the multiple conductive layers 52Ap, conductive layer 52B, and conductive layer 52C are aligned in the Y direction with equal pitch P1, but it is not limited to this. For example, the pitch between the adjacent conductive layers 52Ap and 52C, and the pitch between the adjacent conductive layers 52B and 52C, may be shorter than the pitch P1 between other wirings. In the following, an explanation will be given mainly as to the configuration different from that in the second embodiment. As to the configurations that are equivalent to those in the first embodiment, explanations will be omitted as appropriate.

FIG. 13 is a plan view illustrating an example of a planar layout of wiring in the vicinity of a row decoder module of a memory device according to a first modification of the second embodiment. FIG. 13 corresponds to FIG. 12 in the second embodiment.

As illustrated in FIG. 13, in the layer D0, the multiple conductive layers 52 may include the multiple conductive layers 52Ap, 52B, and 52Cn.

The conductive layer 52Cn is provided between the conductive layer 52Ap and the multiple conductive layers 52B which are aligned with the pitch P1. The conductive layer 52Cn is a wiring to which a predetermined voltage is not applied at the time of the write operation, the read operation, and so on (that is, in a floating state). The conductive layer 52Cn and the wiring portion of the conductive layer 52Ap adjacent to the conductive layer 52Cn are aligned in the Y direction with the pitch P2 shorter than the pitch P1. The conductive layer 52Cn and the conductive layer 52B adjacent to the conducive layer 52Cn are aligned in the Y direction with the pitch P2. The conductive layer 52Cn has the line width W2. That is, the space between the conductive layer 52Ap and the conductive layer 52Cn, which are adjacent to each other, and the space between the conductive layer 52B and the conductive layer 52Cn, which are adjacent to each other, become (P2−W1/2−W2/2). As described above, since the conductive layer 52Cn is the wiring in the floating state, different from the conductive layers 52Ap and 52B, it is not subject to restrictions regarding the wiring resistance. Therefore, the pitch P2 and the line width W2 with respect to the conductive layer 52Cn can be made shorter than the pitch P1 and the line width W1 with respect to the conductive layers 52Ap and 52B, which are subject to the constrains regarding the wiring resistance.

The space (not including the line width of the conductive layer 52Cn) between the conductive layer 52Ap and the conductive layer 52B, which are adjacent to each other via the conductive layer 52Cn, becomes (P2−W1/2−W2/2)×2. The space (P2−W1/2−W2/2)×2 between the conductive layer 52Ap and the conductive layer 52B is designed such that the breakdown voltage of the insulator provided in this space exceeds the potential difference that may occur between the conductive layer 52Ap and the conductive layer 52B.

As described above, by making the pitch between the conductive layer 52Ap and the conductive layer 52Cn, and between the conductive layer 52B and the conductive layer 52Cn, to the pitch P2 shorter than the pitch P1, it is possible to minimize the layout size of the conductive layer 52 in the layer D0 within the range that satisfies the breakdown voltage constraints.

### 2.3.2 Second Modification of Second Embodiment

In the first modification of the second embodiment, the explanation has been given as to the case where the line width W3 of the pad portion of the conductive layer 52Ap is longer than the line width W1 of the conductive layer 52B, but it is not limited to this. In the following, an explanation will be given mainly as to the configuration different from that in the first modification of the second embodiment. As to the configurations equivalent to those in the first modification of the second embodiment, explanations will be omitted as appropriate.

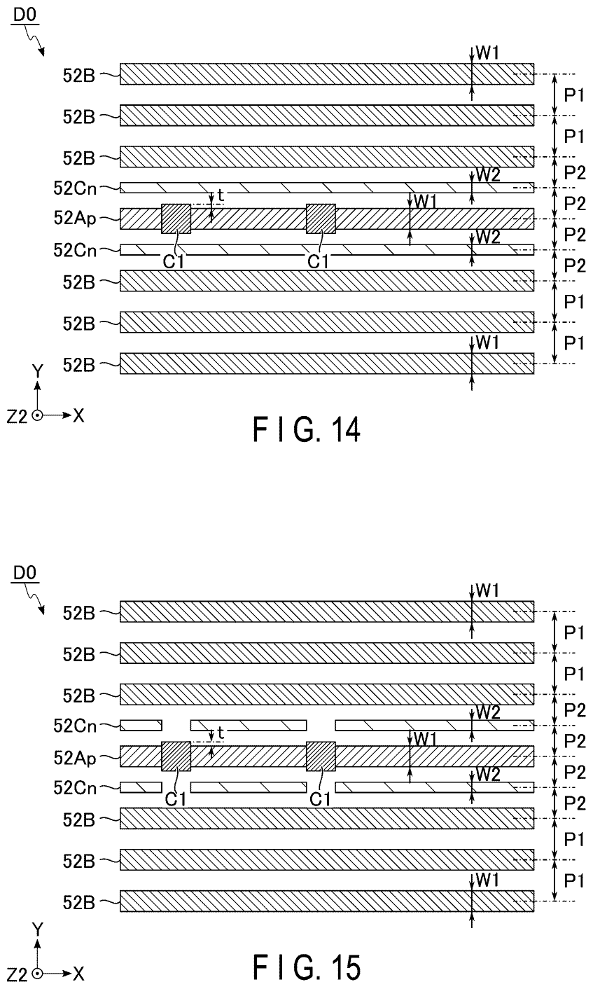

FIG. 14 is a plan view illustrating an example of a planar layout of wiring in the vicinity of a row decoder module of a memory device according to a second modification of the second embodiment. FIG. 14 corresponds to FIG. 13 in the first modification of the second embodiment.

As illustrated in FIG. 14, the line width W3 of the pad portion of the conductive layer 52Ap may be equal to the line width W1 of the conductive layer 52B. In this case, the contact C1 connected to the pad portion of the conductive layer 52Ap may include a portion that does not overlap with the pad portion when viewed in the Z direction.

At the connection portion connected with the contact C1, the space (not including the conductive layer 52Cn) between the conductive layer 52Ap and the conductive layer 52B becomes shorter than the space (P2−W1/2−W2/2)×2 by a length t which is the length that the contact C1 extends from the pad portion of the conductive layer 52Ap. For this reason, in a case where the connection is made with the contact C1 being extended from the pad portion of the conductive layer 52Ap, it is so designed that the breakdown voltage of the insulator provided in the space (P2−W1/2−W2/2)×2−t) between the conductive layer 52B and the conductive layer 52Ap at the connection portion connected with the contact C1 exceeds the potential difference that may occur between the conductive layer 52Ap and the conductive layer 52B.

### 2.3.3 Third Modification of Second Embodiment

In the second modification of the second embodiment, the explanation has been given as to the case where the breakdown voltage of the insulator provided in the space (P2−W1/2−W2/2)×2−t) between the conductive layer 52B and the conductive layer 52Ap at the connection portion connected with the contact C1 exceeds the potential difference that may occur between the conductive layer 52Ap and the conductive layer 52B, but it is not limited to this. In the following, an explanation will be given mainly as to the configuration different from that in the second modification of the second embodiment. As to the configurations equivalent to those in the second modification of the second embodiment, explanations will be omitted as appropriate.

FIG. 15 is a plan view illustrating an example of a planar layout of wiring in the vicinity of a row decoder module of a memory device according to a third modification of the second embodiment. FIG. 15 corresponds to FIG. 14 in the second modification of the second embodiment.

As illustrated in FIG. 15, in the region between the conductive layer 52B and the conductive layer 52Ap at the connection portion connected with the contact C1, the conductive layer 52Cn may be divided in the X direction. Such a divided structure of the conductive layer 52Cn can be realized by using an SRAF (sub-resolution assist feature) for the mask pattern used at the time of forming the wiring pattern of the layer D0.

In this case, the space between the conductive layer 52B and the conductive layer 52Ap at the connection portion connected with the contact C1 becomes longer by the line width W2 of the conductive layer 52Cn than the region where the conductive layer 52Cn is provided. With this configuration, in the region where the conductive layer 52Cn is not provided, the thickness of the insulator provided in the space between the conductive layer 52Ap and the conductive layer 52B can be made to ((P2−W1/2−W2/2)×2−t+W2). Hence, the breakdown voltage of the insulator can be locally increased by the line width W2 of the conductive layer 52Cn. Therefore, it is possible to mitigate an influence caused by the contact C1 extending from the conductive layer 52Ap.

### 3. Third Embodiment

Next, an explanation will be given as to the memory device according to a third embodiment. In the third embodiment, the planar layout of a case where the wiring, which does not generate a large potential difference with respect to the pad, is arranged around the wiring that functions as the pad is illustrated. In the following, an explanation will be given mainly as to the configuration different from that in the second embodiment. As to the configurations equivalent to those in the second embodiment, explanations will be omitted as appropriate.

### 3.1 Configuration

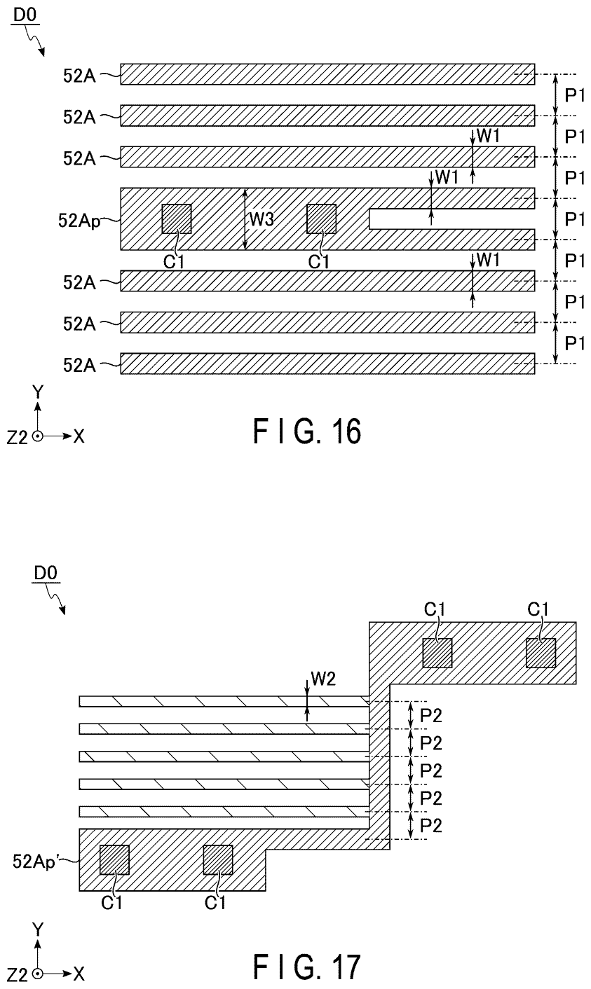

FIG. 16 is a plan view illustrating an example of a planar layout of wiring in the vicinity of a low decoder module of the memory device according to the third embodiment. FIG. 16 corresponds to FIG. 12 in the second embodiment.

As illustrated in FIG. 16, in the layer D0, the multiple conductive layers 52 include the multiple conductive layers 52Ap and 52A.

The multiple conductive layers 52A are a group of wirings in which a relatively large potential difference does not occur mutually at the time of the write operation, the read operation, and so on. The multiple conductive layers 52A are aligned in the Y direction in such a manner as to sandwich the conductive layer 52Ap. The multiple conductive layers 52A, which are mutually adjacent to each other, are aligned in the Y direction at equal intervals with the pitch P1. Each of the multiple conductive layers 52A has the line width W1. That is, the space between two adjacent conductive layers 52A becomes (P1−W1).

In a certain operation, between the voltage applied to the multiple conductive layers 52A and the voltage applied to the conductive layer 52Ap, a relatively large potential difference does not occur. For example, in a case where a high voltage is applied to the conductive layer 52Ap, the high voltage may also be applied to the multiple conductive layers 52A. In a case where a low voltage is applied to the conductive layer 52Ap, the low voltage may also be applied to the multiple conductive layers 52A.

The wiring portion of the conductive layer 52Ap and the conductive layer 52A adjacent to the conductive layer 52Ap are aligned in the Y direction with the pitch P1. That is, the space between the conductive layer 52Ap and the conductive layer 52A, which are adjacent to each other, becomes (P1−W1).

### 3.2 Effect of the Third Embodiment

According to the third embodiment, the conductive layer 52Ap, which includes the pad portion, and the multiple conductive layers 52A are aligned at equal intervals with the pitch P1. With this configuration, the lithography margin can be improved compared to a case where the pitch between the conductive layer 52Ap and the conductive layer 52A and the pitch between the multiple conductive layers 52 are made different from each other.

The above-described arrangement holds true in a case where a relatively large potential difference does not occur between the conductive layer 52Ap and the conductive layer 52A adjacent to the conductive layer 52Ap. In a case where a relatively large potential difference occurs between the conductive layer 52Ap and the conductive layer adjacent to the conductive layer 52Ap, as in the second embodiment, by interposing the conductive layer 52C in the floating state between the conductive layer 52Ap and the conductive layer adjacent to the conductive layer 52Ap, it is possible to suppress a decrease in the lithography margin while satisfying the requirement for the breakdown voltage.

### 4. Fourth Embodiment

Next, an explanation will be given as to the memory device according to a fourth embodiment. In the fourth embodiment, the planar layout of a case where the conductive layer 52 includes a portion that functions as a current path and a portion that does not function as the current path, is illustrated. In the following, an explanation will be given mainly as to the configuration different from that of the second embodiment. As to the configurations equivalent to those in the second embodiment, explanations will be omitted as appropriate.

### 4.1 Configuration

FIG. 17 is a plan view illustrating an example of a planar layout of wiring in the vicinity of a row decoder module of the memory device according to the fourth embodiment. FIG. 17 corresponds to FIG. 12 in the second embodiment.

As illustrated in FIG. 17, in the layer D0, the multiple conductive layers 52 include a conductive layer 52Ap′. The conductive layer 52Ap′ includes two pad portions, an active wiring portion, and multiple non-active wiring portions.

The two pad portions are mutually aligned in the Y direction.

The active wiring portion extends in the Y direction and connects the two pad portions. The active wiring portion is a portion that functions as a path of the current flowing between the two pad portions.

Each of the multiple non-active wiring portions extends in the X direction and includes a first end connected to the active wiring portion. The multiple non-active wiring portions are portions that do not function as the path of the current flowing between the two pad portions. In other words, the multiple non-active wiring portions do not contribute to the function as the wiring of the conductive layer 52Ap′.

The multiple non-active wiring portions are aligned at equal intervals in the Y direction with the pitch P2. Each of the multiple non-active wiring portions has the line width W2. That is, a space between two adjacent non-active wiring portions becomes (P2−W2).

### 4.2 Effects of Fourth Embodiment

According to the fourth embodiment, the non-active wiring portions are aligned in the Y direction at equal intervals with the pitch P2 which is shorter than the pitch P1. With this configuration, it is possible to suppress a reduction in the lithography margin compared to the case where the non-active wiring portions are aligned with the pitch P1.

### 5. Other

The above-described embodiments can apply various modifications.

In the above-described fourth embodiment, the explanation has been given as to the case where the non-active wiring portions are connected to the active wiring portion, but it is not limited to this. For example, the non-active wiring portions may be divided from the active wiring portion. In this case, the non-active wiring portions become the wiring in the floating state. With this configuration, unnecessary portions other than the current path are cut off from the conductive layer 52Ap, thus a wiring capacitance of the conductive layer 52Ap′ can be reduced. However, in the case where the non-active wiring portions are divided from the active wiring portion, there is a possibility that the lithography margin at the divided portion may decrease. For this reason, from the view point of improving the lithography margin, it is preferable that the non-active wiring portions are connected to the active wiring portion.

In the first, second, third, and fourth embodiments described above, the explanations have been given as to the memory device such as the NAND flash memory, as an example of the semiconductor device in which the above-described wiring layouts are applied, but it is not limited to this. For example, the above-described wiring layouts can be applied to memory devices other than the NAND flash memory. Furthermore, the above-described wiring layouts can be applied, not limited to the memory devices, to any semiconductor devices that allow a line-and-space wiring layout.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor device comprising:
a control circuit provided on a substrate; and
a plurality of conductors provided in a first layer positioned away from the substrate in a first direction, wherein
the plurality of conductors include a first conductor, a second conductor, a third conductor, and a fourth conductor arranged in this order in a second direction intersecting the first direction,
the control circuit is configured to:
apply, in a case of applying a first voltage to the first conductor, a second voltage different from the first voltage to the third conductor and the fourth conductor; and
be insulated from the second conductor, and
the third conductor and the fourth conductor are aligned in the second direction with a first pitch, and
the first conductor, the second conductor, and the third conductor are aligned in the second direction with a second pitch, the second pitch being equal to or less than the first pitch.

2. The semiconductor device according to claim 1, wherein the second pitch is equal to the first pitch.

3. The semiconductor device according to claim 1, wherein the second pitch is shorter than the first pitch.

4. The semiconductor device according to claim 1, wherein
a space between the first conductor and the third conductor is equal to or more than a threshold value based on a potential difference between the first voltage and the second voltage, and
a space between the first conductor and the second conductor and a space between the third conductor and the second conductor are less than the threshold value.

5. The semiconductor device according to claim 3, wherein the first pitch is equal to or less than 120 nanometers, and the second pitch is equal to or less than 110 nanometers.

6. The semiconductor device according to claim 3, wherein a line width of each of the first conductor, the third conductor, and the fourth conductor is equal to or less than 60 nanometers, and a line width of the second conductor is equal to or less than 55 nanometers.

7. The semiconductor device according to claim 2, wherein the first conductor includes a pad portion having a line width which is an odd multiple of a line width of the third conductor.

8. The semiconductor device according to claim 3, wherein the first conductor includes a pad portion having a line width which is an odd multiple of a line width of the third conductor.

9. The semiconductor device according to claim 8, further comprising a contact extending in the first direction and connected to the pad portion of the first conductor,
wherein the contact includes a portion that does not overlap the first conductor when viewed in the first direction.

10. The semiconductor device according to claim 9, wherein the second conductor is divided, in a third direction intersecting the first direction and the second direction, at a region between the third conductor and a connection portion where the pad portion of the first conductor and the contact are connected.

11. The semiconductor device according to claim 4, wherein the potential difference is equal to or more than 15 V.

12. The semiconductor device according to claim 1, further comprising:
a plurality of wiring layers aligned in the first direction and spaced apart from each other; and
a memory pillar extending in the first direction, portions thereof, which intersect with each of the plurality of wiring layers, functioning as memory cells,
wherein the control circuit is connected to the plurality of wiring layers via the plurality of conductors.

13. A semiconductor device comprising:
a control circuit provided on a substrate;
a plurality of wiring layers aligned in a first direction and spaced apart from each other;
a memory pillar extending in the first direction, portions thereof, which intersect with each of the plurality of wiring layers, functioning as memory cells; and
a plurality of conductors provided in a first layer positioned between the substrate and the plurality of wiring layers, each conductor connecting between the control circuit and a corresponding one of the plurality of wiring layers,
wherein the plurality of conductors include:
a plurality of first conductors and a second conductor aligned in a second direction with a first pitch, and
the second conductor includes a pad portion having a line width that is an odd multiple of a line width of each of the first conductors.

14. A semiconductor device comprising:
a control circuit provided on a substrate; and
a plurality of conductors provided in a first layer positioned away from the substrate in a first direction,
the plurality of conductors include a plurality of first conductors and a second conductor, each connected to the control circuit,
the plurality of first conductors are aligned in a second direction intersecting the first direction with a first pitch, and
wherein the second conductor includes:
a first pad portion;
a second pad portion aligned with the first pad portion in the second direction;
a first wiring portion, extending in the second direction, connecting between the first pad portion and the second pad portion; and
a plurality of second wiring portions, each extending from the first wiring portion toward a third direction intersecting the first direction and the second direction, and being aligned in the second direction with a second pitch shorter than the first pitch.
